(19) United States
(12) Patent Application Publication
(10) Pub. No.: US 2018/0335801 A1
(43) Pub. Date: Nov. 22, 2018

(54) MAGNETICALLY COMPENSATED BUTTON FEEL IN AN ELECTRONIC SYSTEM

(71) Applicant: Apple Inc., Cupertino, CA (US)

(72) Inventors: Timothy W. SCALES, San Francisco, CA (US); Charles W. WERLEY, San Jose, CA (US); Hao ZHU, San Jose, CA (US)

(21) Appl. No.: 15/600,128

(22) Filed: May 19, 2017

(51) Int. Cl. G06F 1/16; H01F 7/02; G01R 33/00; G01R 33/07

(52) U.S. Cl. CPC G06F 1/1626; H01F 7/0252; H01F 7/0278; G01R 33/07; G06F 1/1656; G01R 33/0052

(57) ABSTRACT

An electronic device can include an actuator unit with a button, where the actuator unit requires application of at least a threshold actuation force to an accessible surface of the button. The electronic device may also include a tactile compensation unit that is in physical communication with the actuator unit. The tactile compensation unit is rendered operable when a triggering magnetic element forms a magnetic circuit with the triggering unit, such that the tactile compensation unit operates to maintain the activation of the actuator unit using no more than the threshold actuation force.

### FIELD

The described embodiments relate generally to buttons of electronic devices. More particularly, the described embodiments relate to the tactile feeling of buttons. Even more particularly, the described embodiments relate to devices, systems and methods that retain the original tactile feeling of a button after the electronic device is coupled to an accessory that might change the tactile feeling of the button.

### BACKGROUND

Electronic devices are often designed with precise predetermined factors and standard to ensure consistency in user experience. It has become increasingly common for an electronic device to be coupled with an accessory such as a case. An accessory can provide additional benefits in the form of protection, improved appearance, and/or additional functionalities. However, an accessory may also change the operation of the electronic device and sometimes alter the user experience and feeling of the electronic device.

### SUMMARY

This paper describes various embodiments related to devices, systems and methods that retain the original tactile feeling of a button after an electronic device is coupled to an accessory that might change the tactile feeling of the button.

According to one embodiment, an electronic device is described. The electronic device can include an actuator unit with a button, where the actuator unit requires application of at least a threshold actuation force to an accessible surface of the button. The electronic device may also include a tactile compensation unit that is in physical communication with the actuator unit. The tactile compensation unit can include a triggering unit. The tactile compensation unit is rendered operable when a triggering magnetic element forms a magnetic circuit with the triggering unit, such that the tactile compensation unit operates to maintain the activation of the actuator unit using no more than the threshold actuation force.

According to another embodiment, an electronic system is described. The electronic system can include an electronic device including a housing, an actuator unit having a button, and a tactile compensation unit. Activation of the button may require application of at least a threshold actuation force to an accessible surface of the button. The system may also include an accessory device removably coupled to the electronic device. The accessory device may be formed of a material and include a triggering magnetic element. When the accessory device is coupled to the electronic device, the threshold actuation force of the button is altered. Thus, the tactile compensation unit may include a triggering unit and is rendered operable when the triggering magnetic element of the accessory device forms a magnetic circuit with the triggering unit, thereby causing the tactile compensation unit to compensate for the alteration to the threshold actuation force.

According to yet another embodiment, a method is described. The method may include attaching an accessory device to an electronic device, the accessory device formed of a material including a trigger magnetic element and the electronic device including an actuator unit and a tactile compensation unit. The method may also include compensating, with the tactile compensation unit, for an alteration to a threshold activation force of a button of the actuator unit, the alteration caused by the attachment of the accessory. The compensation step may be performed in response to a magnetic circuit being formed.

Other aspects and advantages of the invention will become apparent from the following detailed description taken in conjunction with the accompanying drawings which illustrate, by way of example, the principles of the described embodiments.

### BRIEF DESCRIPTION OF THE DRAWINGS

The disclosure will be readily understood by the following detailed description in conjunction with the accompanying drawings, wherein like reference numerals designate like structural elements, and in which:

FIG. 1A illustrates an isomeric view of an electronic device in accordance with an embodiment.

FIG. 1B illustrates an isomeric view of an electronic system including the electronic device shown in FIG. 1A being retained in an accessory in accordance with an embodiment.

FIG. 2A is a side view of an actuation system.

FIG. 2B illustrates a force-deflection profile of an actuation system.

FIG. 3 is a block diagram of an example system including an actuator and a tactile compensation unit in accordance with aspects of the invention.

FIGS. 4A and 4B are side views of an electronic device in an uncompensated state and compensated state in accordance with an embodiment.

FIG. 5 is a flowchart of steps in a method for adjusting the tactile feel of a button or actuator according to aspects of the invention.

FIG. 6 is a flowchart of steps in a method for determining different types of accessories that may be coupled to an electronic device.

Those skilled in the art will appreciate and understand that, according to common practice, various features of the drawings discussed below are not necessarily drawn to scale, and that dimensions of various features and elements of the drawings can be expanded or reduced to more clearly illustrate the embodiments of the present invention described herein.

### DETAILED DESCRIPTION

Representative applications of methods and apparatus according to the present application are described in this section. These examples are being provided solely to add context and aid in the understanding of the described embodiments. It will thus be apparent to one skilled in the art that the described embodiments may be practiced without some or all of these specific details. In other instances, well known process steps have not been described in detail in order to avoid unnecessarily obscuring the described embodiments. Other applications are possible, such that the following examples should not be taken as limiting.

In the following detailed description, references are made to the accompanying drawings, which form a part of the description and in which are shown, by way of illustration, specific embodiments in accordance with the described embodiments. Although these embodiments are described in sufficient detail to enable one skilled in the art to practice the described embodiments, it is understood that these examples are not limiting; such that other embodiments may be used, and changes may be made without departing from the spirit and scope of the described embodiments.

Embodiments described herein relate to devices, systems, and methods that generate a magnetic force to interact with a button of an electronic device (e.g., a laptop, a tablet, a smartphone, a smart watch, a remote control, etc.), such that the magnetic force may compensate for any change of the button characteristics caused by an external object or device.

Electronic devices can have one more buttons used as user input. Different types and designs of buttons can each have a different tactile feeling (also can be commonly referred to as “click” feeling). Tactile feeling can be a user feeling of the button when the user depresses the button, which can be associated with the force required to depress the button, the travel distance (also can be referred to as deflection) required to depress the button, the speed of rebounding of the button, etc. The tactile feeling of a button may depend on the material of the button's components, which can change the stiffness and other factors of the button. A button generally can include an actuator unit in contact with a button body. The actuator unit can include a movable electrical contact. The actuation of the actuator unit may require an application of a threshold actuation force to the button for the movable electrical contact to move from a first position corresponding to no-electrical contact to a second position corresponding to an electrical contact. The amount of force required to move the movable electrical contact can usually depend on a spring constant of the actuator unit. A spring constant can be a characteristic of the button that correlates the force needed to compress the button to the distance travelled of the button. Hence, the spring constant can usually represent the stiffness of the button. For example, in some cases, an actuator unit of the button can be formed from a flexible material, such as silicone, rubber, or other suitable polymer materials. The flexible material usually gives the button a softer feeling (i.e. a lower spring constant). In other cases, the actuator unit can be formed a metal. This usually gives the button a crisper or snappier feeling (i.e. a higher spring constant).

The tactile feeling of a button is usually predetermined by the design engineers based on expected desirable user feeling and user experience of the electronic device. For example, in some cases, it may be desirable for buttons to have a crisp tactile feeling to allow fast clicking. This can be achieved by having a button that has a relatively high spring constant and a shorter deflection distance (the distance the movable part of the button travels from the un-depressed state to the activation state). In other cases, it may be desirable for buttons to have a soft feeling and a longer deflection distance to prevent accidental actuations. This can be achieved by having a button that has a relatively low spring constant. Because of some of those reasons, buttons are often designed with a precise predetermined tactile feeling to provide the best user experience.

However, an accessory associated with an electronic device may sometimes alter the original predetermined tactile feeling of a button on the electronic device. In one case, an accessory can take the form of a protective case that might have a layer of material that covers one or more buttons of the electronic device. In such a configuration, at least a portion of the accessory device can become a part of the button stackup whereby mechanical properties of material associated with the accessory affect the overall mechanical response of the button. Hence, an actuation force to activate the button would have to be applied through the portion of the accessory. Oftentimes this could change the tactile feeling of the button because the new button stackup that includes a portion of the accessory covering the button can have a new overall spring constant and may have a new threshold actuation force that can activate the button stackup. For example, an accessory formed from an elastic material such as silicone or leather may make an originally crisp button feels softer because the elastic material has a lower spring constant than the button.

In particular, the electronic devices, systems, and methods may include an actuator and a tactile compensation unit. The actuator may include a predetermined amount of force required to actuate and this force may be altered by the addition of an accessory. Therefore, the tactile compensation unit, which may include a biasing unit and a trigger, may be configured to activate and maintain the predetermined amount of force or adjust the amount of force required to activate the actuator. The tactile compensation unit may be activated by a trigger element in the accessory, and may include a biasing element which is used to generate a compensation force.

The devices, systems, and methods described herein can be used with any suitable electronic devices and accessories, such as those sold by Apple Inc. of Cupertino, Calif. The magnetic elements can be permanent magnets such as magnetized ferromagnetic material, ceramic rare earth magnets such as samarium-cobalt, neodymium, or other rare earth alloy magnets. The magnetic elements can also be any magnetic elements that can generate a magnetic field such as any electromagnets or can be formed from a ferromagnetic material that is responsive to a magnetic field.

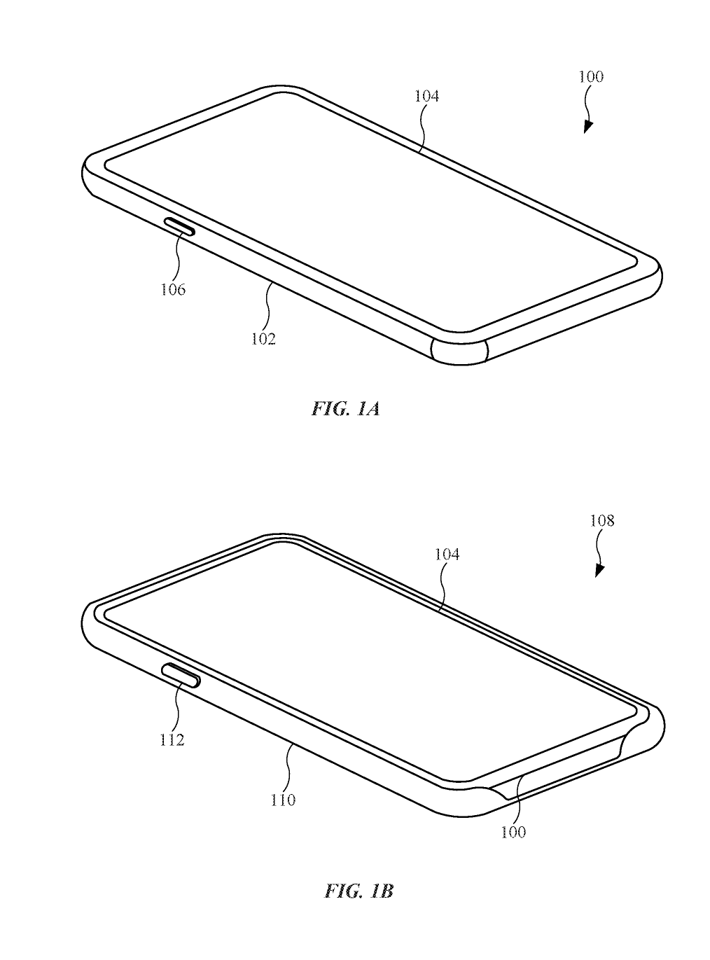

These and other embodiments are discussed below with reference to FIGS. 1A-6; however, those skilled in the art will readily appreciate that the detailed description given herein with respect to these figures is for explanatory purposes only and should not be construed as limiting.

FIG. 1A shows an isometric view of representative electronic device 100. In some embodiments, the electronic device 100 can be an electronic device such as a laptop computer. In other embodiments, the electronic device 100 can be a portable electronic device such as a smartphone or a tablet. It should be noted that while electronic device 100 shown in FIG. 1A may take the form of a mobile communication device, such as a smartphone, embodiments described herein are not limited to a portable electronic device. Embodiments described herein can be any devices that include a button.

Electronic device 100 can include a housing 102 that defines an internal cavity and that carries within the internal cavity internal components and circuitry, such as circuit boards, memory, batteries, and various input/output support devices, as non-limiting examples. The housing 102 can be formed from a metal (or metals), such as aluminum or an alloy that includes aluminum. Other materials are also possible, such as a rigid plastic or ceramic. Electronic device 100 can also include a display assembly 104 designed to present visual information, in the form of images and/or video. The display assembly 104 can include a capacitive touch sensitive layer designed to receive a touch input to alter the visual information.

Electronic device 100 can additionally include various buttons used as user control inputs of electronic device 100. The buttons can be carried by the electronic device at different locations along the housing at different openings of the housing. As a non-exclusive and non-limiting example, a button 106 can be located along the side of housing 102. Additional buttons that are not shown in FIG. 1 can also be carried by electronic device 100.

Now referring to FIG. 1B, it is an isometric view of a representative electronic system 108 in accordance with some embodiments. Electronic system 108 can include electronic device 100 and an accessory 110. Accessory 110 can also be a case, a cover, a flap, a folio, or a wallet. Accessory 110 can be protective in nature or simply an aesthetically pleasing adornment, or in some embodiments can be both protective and ornamental in nature. In some cases, accessory 110 can be an electronic accessory that can provide additional functionalities to electronic device 100 and sometimes also provides protection to electronic device 100. For example, accessory 110 can be a combination of a keyboard and a cover. In one case, such as the configuration shown in FIG. 1B, accessory 110 can take the form of a case. Accessory 110 can include sidewalls and a back panel (or generally a body in any shape) cooperating to define a cavity for accepting and retaining electronic device 100 at least partially by interference fit (i.e. frictional fit). Hence, electronic device 100 can be removably coupled to and retained by accessory 110. In other cases, accessory 110 can simply be removably attached to electronic device 100 by frictional fit, magnetic attraction, or other interactions.

Accessory 110 can be formed from any suitable material or materials. In one embodiment, accessory 110 can include a rigid material, such as a polycarbonate, fiberglass, or other rigid polymer such that accessory 110 maintains its general shape. However, the material should be at least partially deformable such that electronic device 100 can be placed within and removed from accessory 110. In some cases, accessory 110 can be formed from a more flexible material, such as silicone, other suitable polymer, or leather. It should be understood that any suitable material that is capable receiving an electronic device may be employed and are not limited to those listed above, including suitable polymeric materials (e.g. polypropylene, polyvinyl chloride, polyurethane), fabrics, metal (e.g., aluminum), wood, synthetic and/or natural leathers, with or without reinforcement or any combination thereof.

FIG. 1B shows a view when electronic device 100 is being coupled to accessory 110. In such configuration, some of the components of electronic device 100 can be covered by accessory 110 while other components can still be exposed. For example, in the particular case shown in FIG. 1B, display assembly 104 can be exposed while side button 106 can be covered by the sidewall of accessory 110. Accessory 110 may have an area 112 that generally corresponds to the shape of button 106 to allow button 106 to be depressed even though button 106 is covered by accessory 110.

Since one or more buttons may be covered by accessory 110 when electronic device 100 is coupled to accessory 110, the material from which accessory 110 is formed can affect the tactile feeling of each covered button because the tactile feeling can depend on the material and design of accessory 110. The change in tactile feeling can impact the general user experience. Because the original tactile feeling of an uncovered button can be designed by engineers based on the most desirable targeted user feeling of that particular button, it can be advantageous to be able to maintain such original feeling even when accessory 110 is coupled to electronic device 100 and covers one or more buttons of electronic device 100.

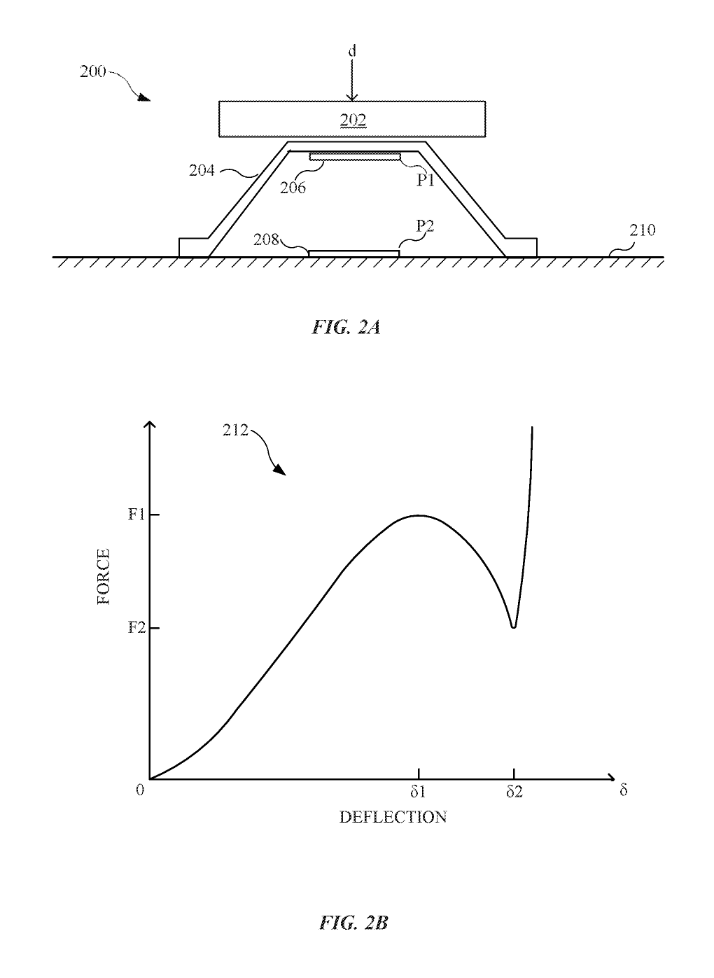

FIG. 2A illustrates a block diagram of a actuator or actuator unit 200. Actuator 200 can include a button body (e.g., a button) 202 that is accessible and an dome switch 204 that can be mechanically coupled to button body 202. Dome switch 204 can be an elastic unit such as a dome, a spring, or any combinations of elastic units, depending on the type and configuration of the actuator 200. Actuator 200 can include a movable electrical contact 206. Movable electrical contact 206 can move at least between a first position as represented by a solid box P1 and a second position as represented by a solid box P2. Actuator 200 can be activated by application of at least a threshold actuation force that depresses button body 202 in a direction of depression as indicated by arrow d. When the actuation force is applied, actuator unit 204 can carry movable electrical contact 206 towards a second electrical contact 208 carried on circuitry 210. In other words, first position P1 can correspond to a position with no-electrical contact and, hence, button system 200 is not activated. Second position P2 can correspond to a position that movable electrical contact 206 is in contact with second electrical contact 208, thus completing the circuit on circuitry 210 and activating the actuator 200.

FIG. 2B illustrates a force-deflection profile 212 of actuator 200 that can affect the tactile feeling of button system 200. The vertical axis represents the force applied to button system 200 (such as the actuation force). The horizontal axis can represent the deflection δ (i.e. distance) of the dome switch 204 from an un-depressed position. When a force is applied to actuator 200, the actuator 200 can first exhibit a relatively linear profile from deflection 0 to deflection δ1. This section of the force-deflection profile 212 can largely be governed by the Hooke's Law, which states that the force needed to compress dome switch 204 by a deflection δ is proportional to the deflection δ:

F=k1×δ Eq. (1)

The slope of the force-displacement profile 212 can depend on k1, which can the spring constant of actuator 200. The spring constant of a given button system can depending on the materials and design of the button system and, in particular, the dome switch 204. For example, when the button system is made from a stiffer material, the force required to displace the movable electrical contact 206 for a given deflection δ is larger than the force required when the button system is made from a softer material.

When movable electrical contact 206 reaches δ1 (e.g., when the dome switch is depressed causing the electrical contact to reach δ1), the dome switch 204 might reach a linear elastic limit. The linear elastic limit may represent the maximum distance that actuator 200 continues to exhibit linear force-deflection relationship. Beyond the linear elastic limit, dome switch 204 might buckle, collapse or undergo some form of plastic deformation that is no longer be governed by the Hooke's Law. In one case, less force may be required to continue to depress button system beyond δ1. Hence, force-deflection profile 212 can show a dip between deflection δ1 and δ2. In such case, force F1 may represent a threshold actuation force of actuator 200 because the actuation force may need to exceed F1 in order for dome switch 204 to get pass deflection distance δ1. Deflection δ2 may represent the maximum deflection of actuator 200, which may be the distance between P1 and P2 as shown in FIG. 2A. Movable electrical contact 206 at position P2 (i.e. deflection δ2) can be brought into contact with second electrical contact 220. Beyond deflection δ2, the force-deflection profile may exhibit a vertical or almost vertical relationship, meaning that any additional force will normally not further displace movable electrical contact 206. This is because both movable electrical contact 206 and second electrical contact 208 are in contact.

While the force-deflection profile 212 in FIG. 2B shows a dip between deflection δ1 and δ2, it should be noted that not every force-deflection profile 212 exhibits such a dip. For some actuators 200 in accordance with some embodiments, the distance between P1 and P2 in FIG. 2A may be shorter than the linear elastic limit δ1. Hence, actuator 200 will not buckle, collapse, or undergo any form of plastic deformation before movable electrical contact 206 comes into contact with second electrical contact 208.

The tactile feeling of a button (e.g., button 202) in an actuator unit or system 200 can depend on its force-deflection profile 212. Different actuators 200 can have a different force-deflection profile 212. There can be multiple exemplary ways that can change the tactile feeling of a button system 200 by adjusting its force-deflection profile 212. For example, a pre-existing force can be provided to the button system to assist or resist the actuation force so that the force required to activate the button system is changed. Also, the material of the button system 200 can be changed such that the spring constant k1 of the button system 200 can be adjusted. In other words, the slope of the force-deflection profile from deflection 0 to δ1 can be adjusted based on the materials. Normally, a steeper slope can represent a stiffer button.

The materials from which movable electrical contact 206 and second electrical contact 208 are made can also affect the tactile feeling of button system 200. When movable electrical contact 206 and second electrical contact 208 are brought into contact, the applied actuation force will create a normal force that pushes movable electrical contact 206 away from second electrical contact 208 towards position P1. This normal force can affect the force and speed that button system 200 rebounds back to the un-depressed state. Hence, the materials from which movable electrical contact 206 and second electrical contact 208 are made can change the speed of rebounding of button system 200.

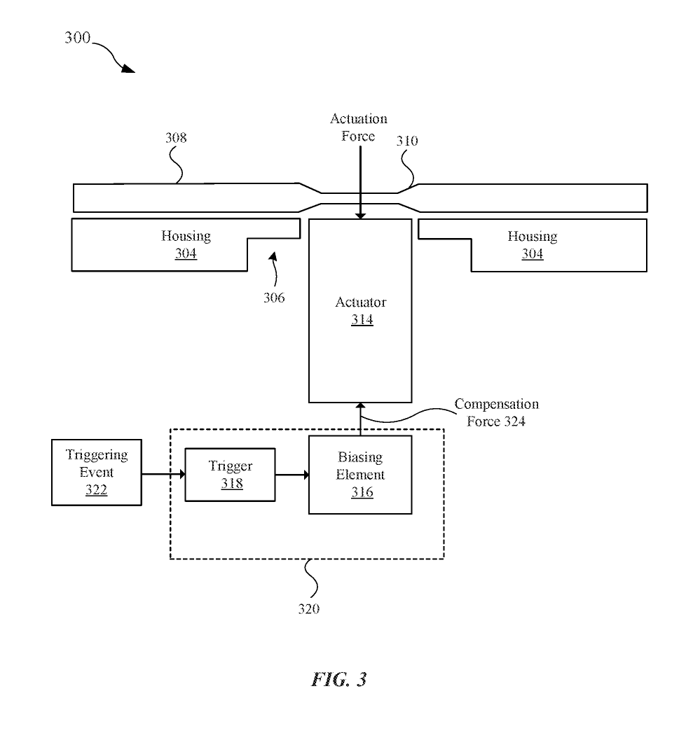

Referring next to FIG. 3, a block diagram of an example system 300 for compensating for the tactile feel of a button or actuator in an electronic device is shown. The system 300 may be positioned with respect to an opening 306 of a housing 304 of an electronic device (not specifically depicted). The system may include a tactile compensation unit 312 and an actuator 314, with the tactile compensation unit including a biasing element 316 and a trigger 318. The system 300 may also include an accessory 308 with a fitted or shaped portion 310 positioned over the actuator 314 (or in particular, positioned over the button of the actuator 314). Although shown generally, the actuator 314 may include a button, a dome switch, an independent or additional biasing element, etc., as is described herein. In one embodiment, actuator 314 may be coupled to a circuit board such as a flex.

When an accessory 308 is added to system 300, accessory 308 can have a layer (e.g., the portion 310) of material that covers the actuator so that actuator 314 is no longer exposed. At the location where the actuator 314 is covered, accessory 308 can include a plate. As such, the actuator 314 can be depressed through depressing the plate with an actuation force. Hence, a new button stackup can be formed, which includes the actuator 314 and the portion of accessory 308 covering the actuator. In some cases, the plate of accessory 308 can itself be a triggering element or can include a triggering element.

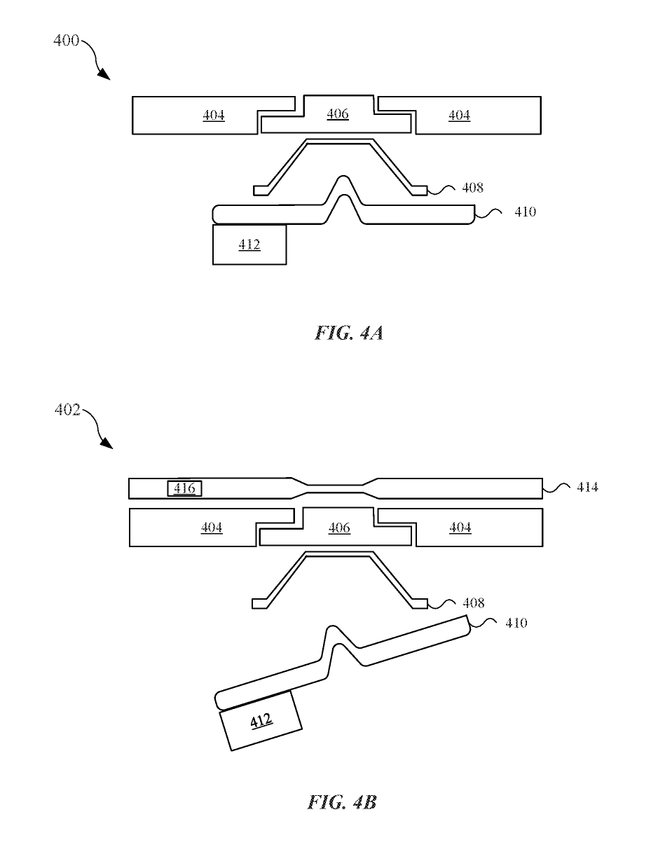

The addition of the accessory 308 may change or alter the amount of force that is predetermined to be required to activate or actuate the actuator 314. As such, the tactile compensation unit 320 or the trigger 318 may be activated by a triggering event 322, which may then apply a compensation force 324 to the actuator 314, thereby compensating for the change of force needed to actuate the actuator 314, or, put alternatively, maintain the amount of force required to actuate the actuator 314. The triggering event 322 may be caused by a trigger, such as a magnetic coupling between a trigger magnetic element (shown in FIGS. 4A and 4B) in the accessory 308 and the trigger 318 of the tactile compensation unit.

In one case, the tactile compensation can take the form of generating a compensating magnetic force that counteracts the effect of an inclusion of accessory 308. Depending on the effect of the inclusion of accessory 308, the compensating magnetic force can either be attractive or repellant to pull or repel plate. Put differently, the coupling of the biasing element 316 and the plate provides a pre-existing force before an actuation force is applied to the new button stackup. Hence, the actuation force required to activate actuator 314 can be changed by this pre-existing force. For example, in one case, after accessory 308 is include, the actuation force required to activate actuator 314 may increase because of the additional layer from accessory 308. To compensate this effect, the compensating magnetic force can be attractive to decrease the actuation force required to depress new button stackup. In such case, biasing element 316 can be a magnet while triggering element can be formed from a ferromagnetic material (or can be a magnet that is in the same pole alignment as the trigger 316), or vice versa.

When accessory 308 is not present, biasing element 316 does not affect any other magnetic element so no pre-existing force is generated. The actuation force required to activate actuator 314 will increase in such case because there is no pre-existing force that assists the actuation. By this tactile compensation mechanism, the threshold force required to depress actuator 314, with or without the inclusion of accessory 308, can be maintained at the same or similar level.

In another embodiment, biasing element 316 can take the form of magnetic coupling between at least two magnetic elements. For example, biasing element 316 can include a first magnetic element that is coupled to actuator 314. The first magnetic element can also be coupled to a second magnetic element that can be mounted on a stationary structure such as housing 304. The first and second magnetic elements can cooperate to provide an attractive force to align the first magnetic element to the second magnetic element. This maintenance of position of the first magnetic element can be used to bias against the depression of actuator 314. For example, actuator 314 can be activated when an actuation force is applied to actuator 314 to overcome the attractive force and depress actuator 314. Actuator 314, which can be coupled to the first magnetic element, can then be returned by the attractive force to its original un-depressed position when the actuation force is removed. Because of the presence of such attractive force constantly pulling first magnetic element back to second magnetic element, any displacement of first magnetic element from second magnetic element can behave similar to a spring and can be calibrated in terms of the magnetic strength of the attractive force. It should be noted that the attractive force can be a sole biasing force of actuator 314 or can take the form of compensation force 322 that assists the biasing of actuator 314.

When an accessory 308 is added to the electronic device, accessory 308 can include a triggering element that affects biasing element 316 to compensate the effect of a portion of accessory 308 covering actuator 314. For example, the triggering element can take the form of a third magnetic element that can be aligned with the first magnetic element of biasing element 316. The third magnetic element can be in opposite pole alignment of the first magnetic element to generate a repellant force that tries to push the first magnetic element away from the second magnetic element. However, in one case, the repellant force may not be as strong as the attractive force between the first and second magnetic elements so that the addition of the repellant force does not overcome the attractive force and inadvertently activate actuator 314. Instead, the repellant force can provide a preexisting force to assist the actuation force applied so that the amount of actuation force required to activate actuator 314 when accessory 308 is included can be reduced. Alternatively, in some cases, it may be desired to increase the stiffness of actuator 314 (i.e. the actuation force required to activate button 302) when accessory 308 is included. In those cases, the magnetic coupling between the third magnetic element and the first magnetic element can instead be attractive to act against any actuation force applied.

In yet another embodiment, actuator 314 can be coupled to a biasing element 316 that provides a compensation force 322 to actuator 314. In other words, biasing element 316 can additionally support actuator 314 so that actuator 314 can be associated with a predetermined spring constant that is correlated with both the spring constant of the actuator 314 and the spring constant of biasing element 316. In one case, the biasing element 316 can be coupled to trigger 318 that reacts to a triggering event.

When an accessory 308 is added to the electronic device, a portion of accessory 308 may cover actuator 314 (e.g., the area of the actuator that includes an accessible surface of a button) so that a new button stackup that includes actuator 314 and the portion of accessory 308 can be formed. Accessory 308 can additionally include a triggering element that can cause a triggering event 320 when accessory 308 is coupled to the electronic device 300.

When a triggering event 320 occurs, trigger 318 can change the interaction between the biasing element 316 and the actuator 314 to negate or at least mitigate the effect of the inclusion of accessory 308. This compensation can include changing the biasing force of the biasing element 316 provided to actuator 314 so that actuator 314 can adjusted based on whether accessory 308 is included or not. In a case where more force is required to activate actuator 314 after accessory 308 is included, trigger 318 can adjust the biasing element 316 to reduce the stiffness of biasing element 316. As a result, the overall stiffness of actuator 314 can also be reduced and the actuation force required to activate actuator 314 can be maintained.

In one specific case, the compensation can take the form of a complete disengagement of biasing element 316 from actuator 314. When a triggering event 320 occurs, trigger 318 can cause biasing element 316 to separate from actuator 314. Hence, the actuator 314 no longer includes the support from biasing element 316. When accessory 308 is removed from the electronic device 300, triggers 318 are no longer under the effect of the triggering element of accessory 308. Biasing element 316 can re-engage with actuator 314 and support actuator 314.

The engagement or disengagement of biasing element 316 can allow actuator 314 to maintain a same or similar tactile feeling regardless whether accessory 308 is included or not because, under this arrangement, actuator 314 is either coupled to biasing element 316 or coupled to accessory 308. In one case, actuator 314 can have a spring constant k1, the portion of accessory 308 covering the actuator 314 can have a spring constant k2, and biasing element 316 can have a spring constant k3 that is equal to spring constant k2. The overall spring constant of the button can be a function of either k1 and k3 or k1 and k2.

Referring next to FIGS. 4A and 4B, a system in an uncompensated state 400 and compensated state 402 is shown. The system includes the electronic device housing 404, a button 406, a dome switch 408, a biasing element 410 (e.g., such as a spring) and a trigger 412. The trigger 412 may be a magnet, and in some embodiments, the biasing element 410 and the trigger 412 form a tactile compensation unit. When no accessory is positioned over the button, the button may include an accessible surface that is accessible by the user and extends between, through, or outward from the opening in the housing 404. When an accessory 414 is positioned over the system, or, more particularly, over the button/actuator of the system 406, the tactile feel of the button 406 during depression may be altered or otherwise affected. Also, the accessible surface of the button 406 may also be obstructed or otherwise covered. Thus, the accessory 414 may include a triggering element 416 (e.g., such as a triggering magnetic element) that magnetically couples with the trigger 412 that is coupled to the biasing element 410. This displaces the biasing element away from the dome switch 408.

Put alternatively, the activation of the trigger 412 by the triggering element 416 in the accessory displaces the biasing element away from the dome switch, thereby compensating for a change in tactile feel (e.g., a change in the predetermined amount of force needed to activate the button) that is caused by the attachment of the accessory to the electronic device. In other embodiments, the amount of displacement of the biasing element may be associated with a particular accessory attachment. As such, the amount of the displacement of the biasing element or even the trigger itself may be utilized to determine what kind of accessory is attached to the system based on the magnetic trigger element 416 of the device.

It should be noted that there can other possible arrangements of tactile compensation units that can be used to negate or at least mitigate the effect of the inclusion of the layer of material to a button system. For example, in one alternative case, when the layer of material is coupled to the button system, instead of having the tactile compensation unit disengaged from the button system, an attractive magnetic force can be generated and a reinforcement spring element can be engaged with the button system to make the button system stiffer.

In some situations, different types of accessory can provide different functionalities to the electronic device. As such, based on the detected type of accessory, the electronic device can initiate different actions that are consistent with the detected type of accessory. For example, the second type of accessory can include an additional camera. Based on the detection of the second type of accessory, the electronic device can automatically initiate a camera software application.

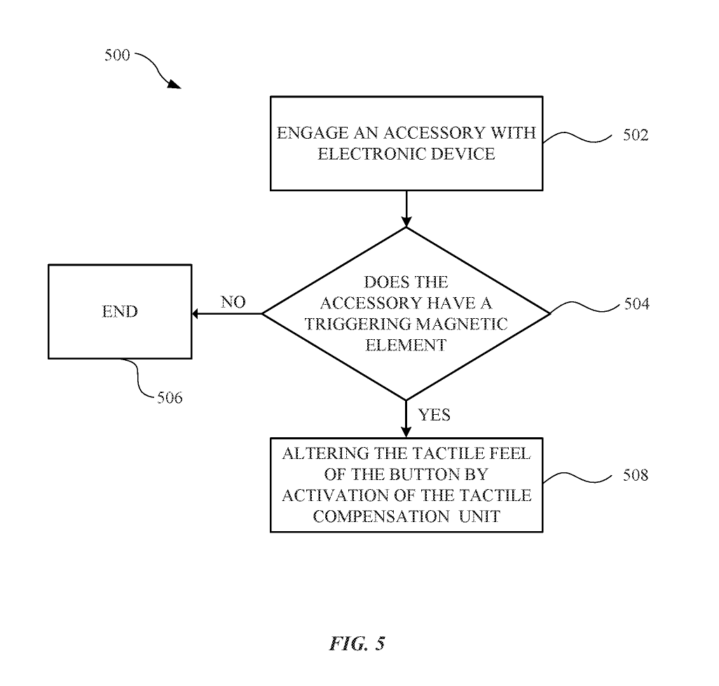

FIG. 5 illustrates a flowchart 500 of steps in a method for tactile compensation of an accessory being attached to a device. At step 502, an accessory is engaged with an electronic device. The accessory may be attached to the electronic device or may simply be placed in proximity to the device. At step 504, in some embodiments, a determination may be made whether the accessory includes a triggering element. If the accessory does not include a triggering element, the method ends at step 506. If the accessory does include a triggering element, the method continues to step 508. In other embodiments, no such determinations are made, and the triggering element of the accessory device causes a compensation unit to activate by triggering an activation trigger by way of attachment or proximate approach. In step 508, the tactile feel of the button is altered by activation of the tactile compensation unit. The tactile compensation unit may be activated by the triggering element in the accessory. Such compensation of the tactile feel is described above.

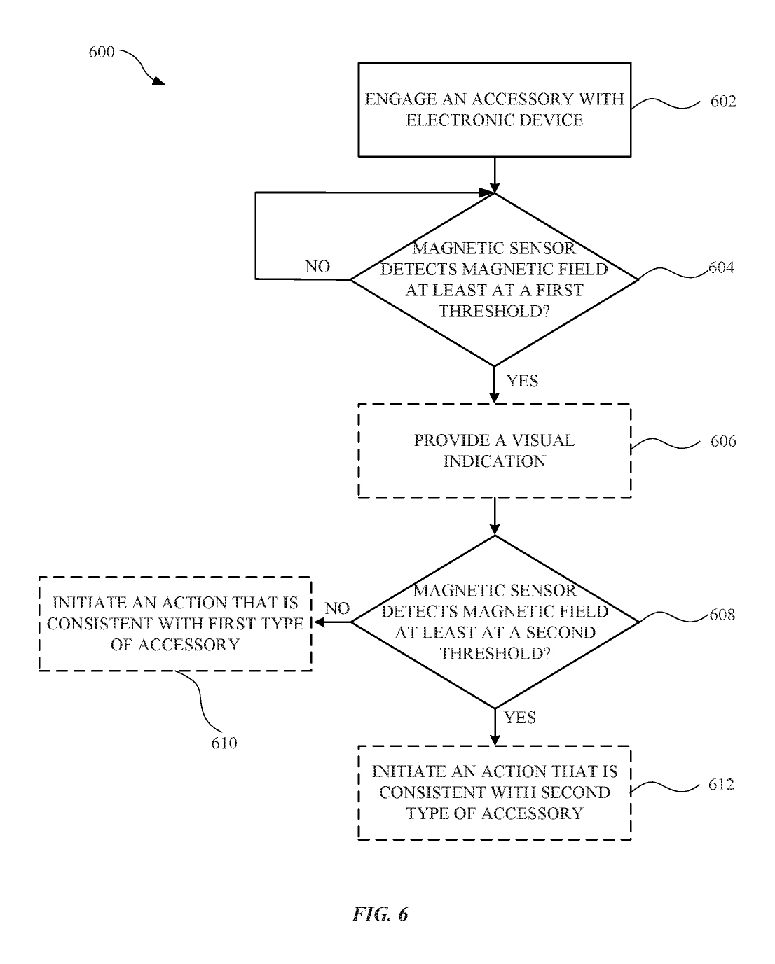

FIG. 6 illustrates a flowchart 600 depicting a method for detecting different types of accessory that is coupled to an electronic device. The electronic device can carry a magnetic sensor such as a Hall effect sensor and/or other sensors configured to determine a type of accessory being attached or provide other additional information to the user of the device, such as indications as to whether an accessory has been attached, partially attached, placed in proximity, or whether the user would like the tactile compensation unit to be activated. At step 602 when an accessory is engaged with the electronic device. At step 604, it is determined whether the accessory is coupled to the electronic device or whether the accessory is properly engaged with the electronic device. The electronic device can make such determination by determining whether the magnetic sensor detects a triggering magnetic field at least at a first threshold value. The detection of at least a first threshold value of triggering magnetic field indicates that a magnetic element is pushed near the magnetic sensor. If no such value of magnetic field is detected, the magnetic sensor can continue to attempt to detect any triggering magnetic field until the detected value crosses or is at least equal to a first threshold.

Optionally, at step 606, if the detected magnetic field is at a first threshold, the electronic device can provide a visual indication that an accessory is engaged with the electronic device. The method can otherwise proceed to step 608, which can be a decision stage for the electronic device to determine which type of accessory is engaged with the electronic device. If the detected value is between the first threshold and the second threshold, the electronic device can determine that a first type of accessory is engaged and may, in optional step 610, automatically initiate an action that is consistent with the engagement of first type of accessory. If the detected value is above both the first and second thresholds, the electronic device can determine that a second type of accessory is engaged and may, in option step 612, automatically initiate an action that is consistent with the engagement of the second type of accessory.

While FIGS. 1A and 1B show that electronic device takes the form of a smartphone, the electronic device in accordance with the described embodiments is not limited to a smartphone. For example, the electronic device can be a laptop computer and the buttons can be the keys of the keyboard of the laptop computer and the accessory can be a keyboard cover. The electronic device can also be a smart watch and the buttons can be buttons that are present on the surface or the side of the smart watch.

The various aspects, embodiments, implementations or features of the described embodiments can be used separately or in any combination. Various aspects of the described embodiments can be implemented by software, hardware or a combination of hardware and software. The described embodiments can also be embodied as computer readable code on a computer readable medium for controlling manufacturing operations or as computer readable code on a computer readable medium for controlling a manufacturing line. The computer readable medium is any data storage device that can store data that can thereafter be read by a computer system. Examples of the computer readable medium include read-only memory, random-access memory, CD-ROMs, HDDs, DVDs, magnetic tape, and optical data storage devices. The computer readable medium can also be distributed over network-coupled computer systems so that the computer readable code is stored and executed in a distributed fashion.

The foregoing description, for purposes of explanation, used specific nomenclature to provide a thorough understanding of the described embodiments. However, it will be apparent to one skilled in the art that the specific details are not required in order to practice the described embodiments. Thus, the foregoing descriptions of the specific embodiments described herein are presented for purposes of illustration and description. They are not targeted to be exhaustive or to limit the embodiments to the precise forms disclosed. It will be apparent to one of ordinary skill in the art that many modifications and variations are possible in view of the above teachings.

1. An electronic device, comprising:
a housing;
an actuator unit carried by the housing, the actuator unit including a surface, wherein at least a threshold application force to the surface activates the actuator unit, the threshold actuation force defining a minimum force to depress the actuator unit; and
a tactile compensation unit carried by the housing, the tactile compensation unit comprising a triggering unit, the tactile compensation unit providing a compensation force in response to a triggering magnetic element external to the housing forming a magnetic circuit with the triggering unit, the compensation force maintaining the threshold actuation force.

2. The electronic device as recited in claim 1, wherein the housing is adapted to be removably coupled to an accessory device that carries the triggering magnetic element such that at least a portion of the accessory device overlays the surface and causes a formation of magnetic circuit.

3. The electronic device as recited in claim 1, wherein the actuator unit further includes a dome switch.

4. The electronic device as recited in claim 1, wherein the tactile compensation unit further comprises a biasing element capable of maintaining the compensation force.

5. The electronic device as recited in claim 4, wherein the biasing element includes a spring element having a spring constant that offsets a spring constant of an accessory device overlaying the surface.

6. (canceled)

7. The electronic device as recited in claim 1, wherein the actuator unit is carried on a circuit board that is movable with the actuation unit in response to least the threshold application force to the actuation unit.

8. An electronic device, comprising:
a housing;
an actuator unit carried by the housing; and
a tactile compensation unit coupled with the actuator unit, wherein at least a threshold actuation force to the actuator unit depresses the actuator unit, the threshold actuation force defining a minimum force to depress the actuator unit, and
wherein the tactile compensation unit includes a triggering unit that forms a magnetic circuit with a triggering magnetic element carried by an accessory device that covers the actuator unit and provides an alteration to the threshold application force, the tactile compensation unit providing, in response to the formation of the magnetic circuit, a compensation force that compensates for the alteration to maintain the threshold actuation force.

9. The electronic device as recited in claim 8, wherein the magnetic circuit is formed when the triggering magnetic element overlays the actuator unit.

10. The electronic device as recited in claim 8, wherein the actuator unit further comprises:
a button;
a dome having at least a portion that is attached to the button; and
an electrical contact carried by a circuit board and adapted to be removably coupled to the dome.

11. The electronic device as recited in claim 10, wherein the tactile compensation unit comprises a biasing element that supports the dome.

12. The electronic device as recited in claim 11, wherein when the tactile compensation unit carries the biasing element away from the dome.

13. The electronic device as recited in claim 11 further comprising a magnetic sensor adapted to detect a position of the trigger magnetic element.

14. The electronic device as recited in claim 8, wherein the triggering unit is coupled to the actuator unit via a biasing element.

15. A method, comprising:
attaching an accessory device to an electronic device, the accessory formed of a material and including a triggering magnetic element, and the electronic device including an actuator unit and a tactile compensation unit, the actuator unit having an accessible surface and a threshold activation force required for activation; and
compensating, with the tactile compensation unit, for an alteration to the threshold activation force of the actuator unit, the alteration caused by the attachment of the accessory device;
wherein the compensation step is performed in response to the tactile compensation unit being rendered operable when the triggering magnetic element of the accessory forms a magnetic circuit with a triggering unit of the tactile compensation unit.

16. The method as recited in claim 15, wherein the magnetic circuit is formed when a layer of the material overlays the accessible surface of the actuator unit.

17. The method as recited in claim 15, wherein the actuator unit further comprises (i) a dome having at least a portion that is attached to the actuator unit, and (ii) an electrical contact carried by a circuit board and adapted to be removably coupled to the dome.

18. The method as recited in claim 15, wherein the compensation step includes maintaining an ability of the actuator unit to be activated with no more than the threshold actuation force.

19. The method as recited in claim 15, wherein the tactile compensation unit comprises a biasing element.

20. The method as recited in claim 19, wherein the biasing element includes a spring element having a spring constant that offsets a spring constant of the layer of material overlaying the accessible surface.
